(19) United States
(12) Patent Application Publication
(10) Pub. No.: US 2023/0261636 A1
(43) Pub. Date: Aug. 17, 2023

(54) OPTIMIZATION OF SURFACE ACOUSTIC WAVE (SAW) RESONATORS WITH RESONANCE FREQUENCY AT UPPER STOPBAND EDGE FOR FILTER DESIGN

(71) Applicant: RF360 EUROPE GMBH, Munich (DE)

(72) Inventors: Matthias KNAPP, Munich (DE); Thomas BAUER, Munich (DE)

(21) Appl. No.: 17/670,281

(22) Filed: Feb. 11, 2022

(51) Int. Cl. H03H 9/145; H03H 9/25; H03H 9/02

(52) U.S. Cl. CPC H03H 9/145; H03H 9/25; H03H 9/02637

(57) ABSTRACT

Aspects of the disclosure relate to devices, wireless communication apparatuses, methods, and circuitry implementing a SAW resonator with a resonance frequency located at the upper stopband edge. One aspect is an apparatus including an electrode structure with an interdigital transducer (IDT) having a center IDT region, a first IDT region, and a second IDT region. The center IDT region has a first pitch level, and the center IDT region has a first pitch level, and, reflectors comprising a first reflector region and a second reflector region, the first reflector region and the second reflector region each comprise a third pitch level lower than the first pitch level and the second pitch level.

### FIELD

The present disclosure relates generally to electronic communications. For example, aspects of the present disclosure relate to surface acoustic wave (SAW) resonators with a resonance frequency located at the upper stopband edge.

### BACKGROUND

Electronic devices include traditional computing devices, such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content, such as voice, video, packet data, messaging, broadcast, and so on. These systems may be capable of supporting communication with multiple users by sharing the available system resources (e.g., time, frequency, and power). Aspects of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering signals in many applications. Using a piezoelectric material as a vibrating medium, acoustic resonators operate by transforming an electrical signal wave, that is propagating along an electrical conductor, into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. The smaller filter device permits acoustic resonators to be used in electronic devices having size constraints, such as the electronic devices enumerated above (e.g., particularly including portable electronic devices, such as cellular phones).

### SUMMARY

Disclosed are systems, apparatuses, methods, and computer-readable media for electronic communications and, more specifically, to devices, wireless communication apparatuses, and circuitry implementing a SAW resonator with a resonance frequency located at the upper stopband edge.

In one example, a resonator is provided. The resonator comprises an interdigital transducer (IDT) positioned at a surface of the piezoelectric material, the IDT comprising a first busbar; a second busbar parallel to the first busbar; a plurality of IDT electrode fingers comprising first IDT electrode fingers extending from the first busbar toward the second busbar and second IDT electrode fingers extending from the second busbar toward the first busbar, the IDT having a plurality of IDT regions including a first IDT region, a second IDT region, and a center IDT region between the first IDT region and the second IDT region, wherein, a pitch of the IDT electrode fingers in the center IDT region is at a first pitch level, the pitch of the IDT electrode fingers in the first IDT region is at a second pitch level, the pitch of the IDT electrode fingers in the second IDT region is at the second pitch level, and the second pitch level is higher than the first pitch level; a first reflector positioned at the surface of the piezoelectric material, the first reflector comprising first reflector electrode fingers and having a first reflector region; a second reflector positioned at the surface of the piezoelectric material, the second reflector comprising second reflector electrode fingers and having a second reflector region; wherein the IDT is positioned between the first reflector and the second reflector, and wherein a reflector pitch of the first reflector in the first reflector region and the second reflector in the second reflector region is at a third pitch level that is lower than the first pitch level and the second pitch level.

In some aspects, the second pitch level is chirped.

In some aspects, the second pitch level of the first IDT region increases from a lower level to a higher level towards the first reflector region.

In some aspects, the second pitch level of the second IDT region increases from the lower level to the higher level towards the second reflector region.

In some aspects, at least some electrode fingers of the IDT electrode fingers in at least one of the first IDT region or the second IDT region have an associated pitch level that is increased compared to the first pitch level of the center IDT region.

In some aspects, the associated pitch level is increased by less than approximately 5% compared to the first pitch level of the center IDT region.

In some aspects, the piezoelectric material comprises lithium niobate (LiNbO₃).

In some aspects, the piezoelectric material comprises a piezoelectric layer having a thickness x and the piezoelectric material comprises a piezoelectric layer having a thickness x.

In some aspects, the cut-angle comprises Euler angles of (0°/125°±15°/0°)

In some aspects, the piezoelectric material comprises a cut-angle layer configured for excitement and propagation of a Rayleigh wave as a main mode.

In another example, an electrode structure is provided. The electrode structure comprises: an interdigital transducer (IDT) having a center IDT region, a first IDT region, and a second IDT region, wherein the center IDT region has a first pitch level, and wherein the first IDT region and the second IDT region each have a second pitch level higher than the first pitch level; and reflectors comprising a first reflector region and a second reflector region, wherein the first reflector region and the second reflector region each comprise a third pitch level lower than the first pitch level and the second pitch level.

In another example, a method for operation of a resonator is provided. The method includes: exciting an acoustic wave within a piezoelectric material with a Rayleigh wave as a main propagating acoustic wave mode via an interdigital transducer (IDT) and reflectors of the resonator, wherein the IDT has a center IDT region, a first IDT region, and a second IDT region, wherein the reflectors comprise a first reflector region and a second reflector region, and wherein the center IDT region has a first pitch level, the first IDT region and the second IDT region each have a second pitch level higher than the first pitch level, and the first reflector region and the second reflector region each have a third pitch level lower than the first pitch level and the second pitch level.

In another example, an apparatus is provided. The apparatus comprises means for generating a Rayleigh wave as a main propagating acoustic wave in a resonator.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF THE DRAWINGS

FIG. 1A is a diagram of a perspective view of an example of an electroacoustic device.

FIG. 1B is a diagram of a side view of the electroacoustic device of FIG. 1A.

FIG. 2 is a diagram of a top view of an example of an electrode structure of an example electroacoustic device.

FIG. 3A is a diagram of a perspective view of another example of an electroacoustic device.

FIG. 3B is a diagram of a side view of the electroacoustic device of FIG. 3A.

FIG. 4 is a diagram of a view of an example electrode structure of a resonator.

FIG. 5A is a diagram of a side view of a layer stack of an electroacoustic device, which generates a shear wave.

FIG. 5B is a diagram showing a side view of a layer stack of the disclosed electroacoustic device, which generates a Rayleigh wave, in accordance with examples described herein.

FIG. 6A is a graph showing the differences in pitch versus resonance frequency for the electroacoustic device of FIG. 5A and the disclosed electroacoustic device of FIG. 5B.

FIG. 6B is a graph showing the differences in capacitance versus pitch for the electroacoustic device of FIG. 5A and the disclosed electroacoustic device of FIG. 5B.

FIG. 6C is a table showing the differences in device size for the electroacoustic device of FIG. 5A and the disclosed electroacoustic device of FIG. 5B.

FIG. 7A are performance graphs for the electroacoustic device of FIG. 5A, which shows the longitudinal spurious modes located below the resonance frequency at the lower stopband edge.

FIG. 7B are performance graphs for the disclosed electroacoustic device of FIG. 5B, which shows the longitudinal spurious modes located above the resonance frequency at the upper stopband edge, in accordance with examples described herein.

FIG. 8A is a diagram of a view of the disclosed electroacoustic device, in accordance with examples described herein.

FIGS. 8B and 8C are performance graphs for the disclosed electroacoustic device of FIG. 8A comprising various different pitch ratios (R1, R2, R3, R4), in accordance with examples described herein.

FIGS. 8D and 8E are performance graphs for the disclosed electroacoustic device of FIG. 8A comprising various different trapping lengths (L1, L2, L3, L4), in accordance with examples described herein.

FIG. 9 is a flowchart illustrating a method of operation of the disclosed electroacoustic device, in accordance with examples described herein.

FIG. 10 is a schematic representation of an exemplary filter that may employ the disclosed electroacoustic device, in accordance with examples described herein.

FIG. 11 is a functional block diagram of at least a portion of an example of a simplified wireless transceiver circuit in which the disclosed electroacoustic device described herein may be employed, in accordance with examples described herein.

FIG. 12 is a diagram of an environment that includes an electronic device that includes a wireless transceiver, such as the transceiver circuit of FIG. 11, in accordance with examples described herein.

### DETAILED DESCRIPTION

The detailed description set forth below in connection with the appended drawings is intended as a description of exemplary implementations and is not intended to represent the only implementations in which the invention may be practiced. The term “exemplary” used throughout the description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

Electroacoustic devices are being designed to cover more frequency ranges (e.g., 500 megahertz (MHz) to six (6) gigahertz (GHz)), to have higher bandwidths (e.g., up to twenty-five (25) percent (%)), and to have improved efficiency and performance. Examples of such electroacoustic devices include SAW resonators, which employ electrode structures on a surface of a piezoelectric material. In general, certain SAW resonators are designed to cause propagation of an acoustic wave in a particular direction through the piezoelectric material (e.g., the main acoustic wave mode). As described herein, SAW devices can be referred to as resonators or electroacoustic resonators. Aspects of the present disclosure are directed to RF filters (e.g., SAW resonators) for filtering a signal for a particular frequency or range of frequencies.

The evolution of next-generation mobile communication systems requires electroacoustic devices (e.g., SAW resonators) to have a combination of various performance criteria, such as a large electromechanical coupling coefficient (k2) and a low temperature coefficient of frequency (TCF). Additionally, miniaturization of these devices, especially in low band applications, is becoming increasingly important. A possible solution to reduce chip size is to reduce the velocity of the propagating wave of these electroacoustic devices and, therefore, reduce the pitch of the interdigital transducer (IDT) for a desired resonant frequency.

SAW filter devices implemented on a sandwich substrate system provide a combination of a large k2, a low TCF, and a high quality factor (Q). In many applications, a shear wave is used as the main propagating wave for these devices. Shear wave devices generally have a resonance frequency at the lower stopband edge. Using a Rayleigh wave, instead of a shear wave, as the main propagating wave, reduces the velocity of the wave. Thus, a lower pitch of the interdigital transducer may be used for devices that use a Rayleigh wave, than for devices that use a shear wave, in order to achieve the desired frequency, which directly leads to a reduction in chip size of the device.

The present disclosure provides a spurious-free one-port resonator for a sandwich-based layer stack that uses a Rayleigh wave and has a resonance at the upper stopband edge. Since the disclosed resonator generates a resonance at the upper stopband edge (as opposed to generating resonance at the lower stopband edge as many commonly used resonators), other design techniques to prevent spurious modes, such as Fabry-Perot resonances, may be less effective for the disclosed resonator. Instead, by optimizing a pitch ratio together with a slope of the pitch in a transition region between the IDT and the reflectors) of the disclosed resonator, the longitudinal spurious modes can be suppressed. The disclosed Rayleigh wave device exhibits a high k2 and low TCF, which is needed for fulfilling the specifications of applications within various different frequency band ranges. Additional details regarding the disclosed SAW resonator with a resonance frequency located at the upper stopband edge, as well as specific implementations, are described below.

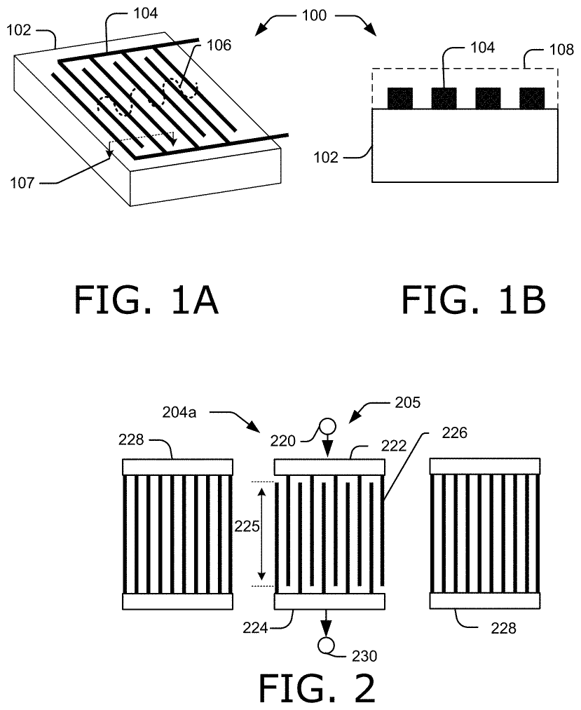

FIG. 1A is a diagram of a perspective view of an example of an electroacoustic device 100. The electroacoustic device 100 may be configured as, or be a portion of, a SAW resonator. In certain descriptions herein, the electroacoustic device 100 may be referred to as a SAW resonator. The electroacoustic device 100 includes an electrode structure 104, that may be referred to as an interdigital transducer (IDT), on the surface of a piezoelectric material 102. The electrode structure 104 generally includes first and second comb shaped electrode structures (conductive and generally metallic) with electrode fingers extending from two busbars towards each other arranged in an interlocking manner in between two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a side view of the electroacoustic device 100 of FIG. 1A, along a cross-section 107 shown in FIG. 1A. The electroacoustic device 100 is illustrated by a simplified layer stack including a piezoelectric material 102 with an electrode structure 104 disposed on the piezoelectric material 102. The electrode structure 104 is conductive and generally formed from metallic materials. The piezoelectric material may be formed from a variety of materials such as quartz, lithium tantalate (LiTaO3), lithium niobate (LiNbO3), doped variants of these, or other piezoelectric materials. It should be appreciated that more complicated layer stacks (e.g., four (4) layers, six (6) layers, etc.), including layers of various materials, may be possible within the stack. For example, optionally, a temperature compensation layer 108 (denoted by the dashed lines) may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 2 is a diagram of a top view of an example of an electrode structure 204a of an example electroacoustic device 100. FIG. 2 generally illustrates a one-port configuration. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222.

In the direction along the busbars 222 and 224, there is an overlap region including a central region where a portion of one finger overlaps with a portion of an adjacent finger (as illustrated by the central region 225). The central region 225 including the overlap may be referred to as the aperture, track, or active region where electric fields are produced between fingers 226 to cause an acoustic wave to propagate in the piezoelectric material 102. The periodicity of the fingers 226 is referred to as the pitch of the IDT. The pitch may be indicted in various ways. For example, in certain aspects, the pitch may correspond to a magnitude of a distance between fingers in the central region 225. The distance may be defined, for example, as the distance between center points of each of the fingers (and may be generally measured between a right (or left) edge of one finger and the right (or left) edge of an adjacent finger when the fingers have uniform thickness). As described herein, a “higher” pitch refers to sections of an IDT where electrode fingers have greater distances between adjacent electrode fingers, and a “lower” pitch refers to sections of an IDT where electrode fingers have lower distances between adjacent electrode fingers. In certain aspects, an average of distances between adjacent fingers may be used for the pitch. Having sections of an IDT with electrode fingers having a given pitch characteristic different from pitch characterizations of other sections of an IDT allows for selection or control of the signals (e.g., waves) that propagate through the IDT. The frequency at which the piezoelectric material vibrates is a self-resonance (also called a “main-resonance”) frequency of the electrode structure 204a. The frequency is determined at least in part by the pitch of the IDT 205 and other properties of the electroacoustic device 100.

In some examples, the pitch characteristics of sections of an IDT can be a constant pitch, where the pitch does not vary significantly over the IDT section (e.g., variances are within manufacturing tolerances, and are designed for a constant average pitch). In other examples, pitch characteristics of an IDT section can include a “chirped” pitch, where the pitch varies in a predefined way over the IDT section. For example, a chirped pitch can include an IDT section where the pitch is designed to change linearly across the IDT section, such that the pitch at one end of the IDT section is at a first value, the pitch at an opposite end of the IDT section is at a second value, and the pitch (e.g., the distance between electrode fingers) changes linearly between the two ends of the IDT section. In other examples, other non-linear variations in pitch value across an IDT section can be used. By combining IDT sections with different pitch characteristics (e.g., a constant pitch at a first value and a constant pitch at a second value, or a constant pitch at a first value in one IDT section and a chirped pitch across a second IDT section), the resonator characteristics can be designed for a given performance as described herein.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the measured admittance or reactance between both terminals (i.e. the first terminal 220 and the second terminal 230) serves as the signal for the electroacoustic device 100.

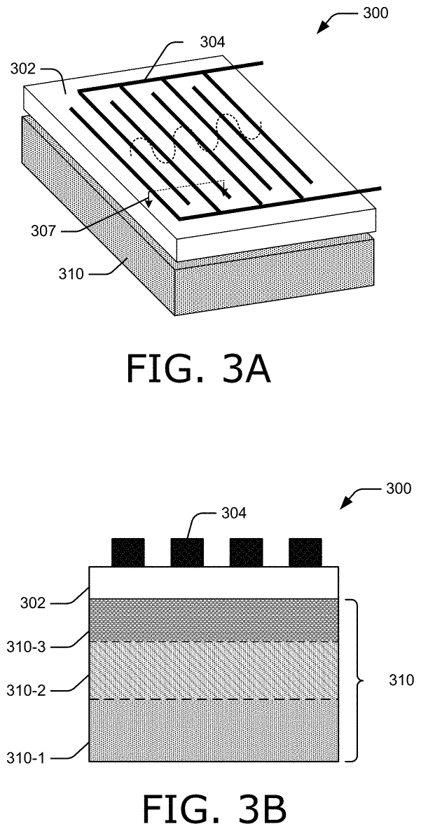

FIG. 3A is a diagram of a perspective view of another example of an electroacoustic device 300. The electroacoustic device 300 (e.g., that may be configured as or be a part of a SAW resonator) is similar to the electroacoustic device 100 of FIG. 1A, but has a different layer stack. In particular, the electroacoustic device 300 includes a thin piezoelectric material 302 that is provided on a substrate 310 (e.g., silicon). The electroacoustic device 300 may be referred to as a thin-film SAW resonator (TF-SAW), in some cases. Based on the type of piezoelectric material 302 used (e.g., typically having higher coupling factors relative to the electroacoustic device 100 of FIG. 1A) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher Q-factor as compared to the electroacoustic device 100 of FIG. 1A. The piezoelectric material 302, for example, may be Lithium tantalate (LiTa03) or some doped variant. Another example of a piezoelectric material 302 for FIG. 3A may be Lithium niobite (LiNbO3). In general, the substrate 310 may be substantially thicker than the piezoelectric material 302 (e.g., potentially on the order of 50 to 100 times thicker as one example—or more). The substrate 310 may include other layers as 310-1, 310-2, and 310-3 (or other layers may be included between the substrate 310 and the piezoelectric material 302).

FIG. 3B is a diagram of a side view of the electroacoustic device 300 of FIG. 3A showing an exemplary layer stack (along a cross-section 307). In the aspect shown in FIG. 3B, the substrate 310 may include sublayers such as a substrate sublayer 310-1 (e.g., of silicon) that may have a higher resistance (e.g., relative to the other layers—high resistivity layer). The substrate 310 may further include a trap rich layer 310-2 (e.g., poly-silicon, aluminum nitride (AlN), silicon nitride (SiN₄), diamond-like carbon (DLC), and dielectric films with a high sound velocity). The substrate 310 may further include a compensation layer (e.g., silicon dioxide (SiO₂) or another dielectric material) that may provide temperature compensation and other properties. These sub-layers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the coupling to the electrode structure 304 and acoustic velocities within the piezoelectric material in different regions of the electrode structure 304 may differ between different types of electroacoustic devices such as between the electroacoustic device 100 of FIG. 1A and the electroacoustic device 300 of FIGS. 3A and 3B.

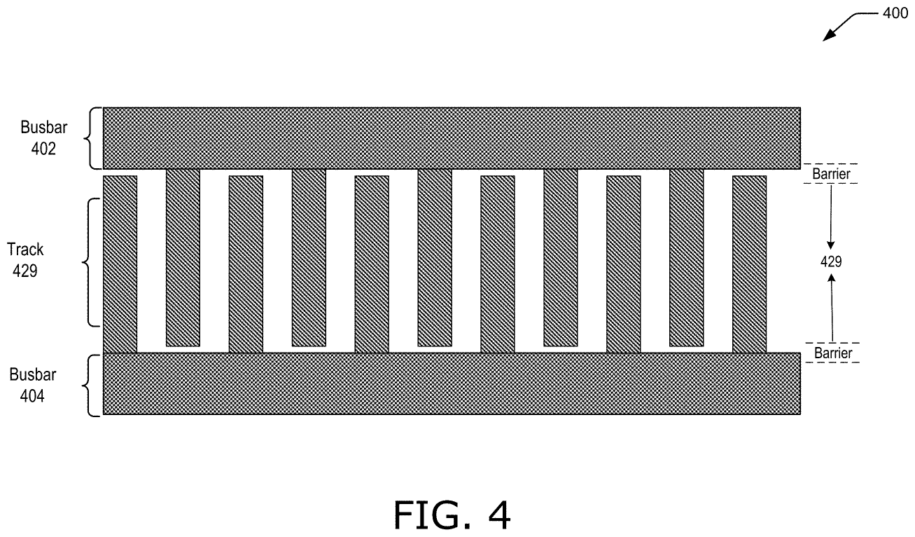

FIG. 4 is a diagram of a view of an example electrode structure 400 of an electroacoustic device (resonator). Just as above, the electrode structure 400 may be referred to as an IDT that can be fabricated on the surface of a piezoelectric material as part of the resonator. The electrode structure 400 includes first and second comb shaped electrodes. The comb teeth are within track 429, and supported by busbar 402 on one side and busbar 404 on the other side. An electrical signal excited across the resonator is transformed into an acoustic wave that propagates within the resonator. The acoustic wave is transformed back into an electrical signal.

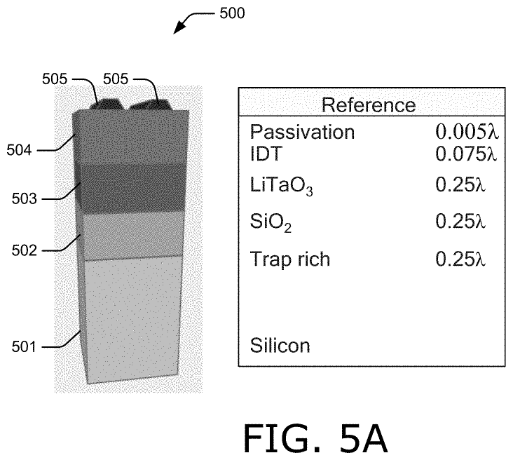

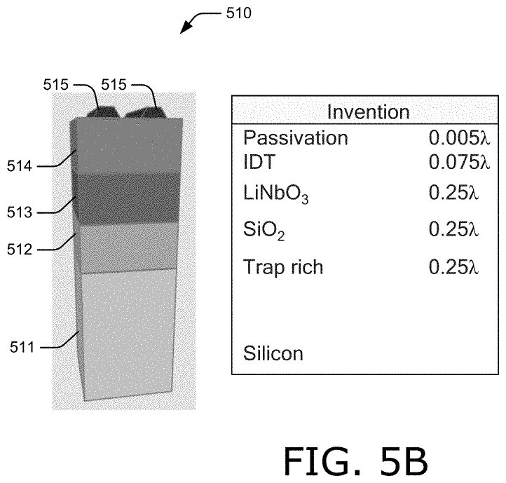

FIG. 5A is a diagram of a side view of a layer stack of an electroacoustic device 500, which generates a shear wave. In particular, the electroacoustic device 500 is a SAW resonator that uses a shear wave as the main propagating wave and has a resonance at the lower stopband edge. In this figure, the electroacoustic device 500 is shown to comprise a plurality of layers. The plurality of layers include a piezoelectric thin film layer (PL) 504, a TCF compensating layer (CL) 503, a substrate (SU) 501, and an optional additional layer (AL) 502 (e.g., a trap rich layer). The electroacoustic device 500 also comprises an electrode structure layer (EL) 505 located on top of the piezoelectric thin film layer 504. For the electroacoustic device 500, the piezoelectric thin film layer 504 comprises lithium tantalate (LiTaO₃). FIG. 5A also includes a table containing exemplary thicknesses of the layers of the electroacoustic device 500 relative to the wavelength (λ).

FIG. 5B is a diagram showing a side view of a layer stack of the disclosed electroacoustic device 510, which generates a Rayleigh wave, in accordance with examples described herein. In particular, the disclosed electroacoustic device 510 is a SAW resonator that uses a Rayleigh wave as the main propagating wave and has a resonance at the upper stopband edge. In this figure, the electroacoustic device 510 is shown to comprise a plurality of layers, which include a piezoelectric thin film layer 514, a TCF compensating layer 513, a substrate 511, and an optional additional layer 512 (e.g., trap rich layer, etc.). The electroacoustic device 510 additionally comprises an electrode structure layer 515 located on top of the piezoelectric thin film layer 514. FIG. 5B also includes a table containing exemplary thicknesses of the layers of the disclosed electroacoustic device 510 relative to the wavelength (λ). It should be noted that the layers of the disclosed electroacoustic device 510 may be designed to have thicknesses other than the exemplary thicknesses shown in the table of FIG. 5B.

The piezoelectric thin film layer 514 is located on top of the TCF compensating layer 513, and in between the electrode structure layer 515 and the TCF compensating layer 513. In this figure, for the disclosed electroacoustic device 510, the piezoelectric thin film layer 514 comprises lithium niobate (LiNbO₃). The piezoelectric thin film layer 514 has a thickness and a cut-angle that favors excitation and propagation of a Rayleigh wave as a main mode. It should be noted that, in one or more examples, other materials (e.g., other crystal materials) that can be cut (e.g., or be generated with a particular crystal orientation) such that they propagate a Rayleigh wave as the main propagating wave may be employed for the piezoelectric thin film layer 514 of the disclosed electroacoustic device 510 other than lithium niobate, as is shown in FIG. 5B. The material (e.g., crystal material) and cut of the piezoelectric thin film layer 514 may be selected such that performance parameters of the electroacoustic device 510, such as k2 quality and TCF of the main mode, are not significantly degraded. In one or more examples, the piezoelectric thin film layer 514 comprises lithium niobate having a crystal cut with Euler angles of (0°/125°±15°/0°). With this cut angle, a high coupling factor k2 can be realized and, thus, a sufficient broadband width can be achieved for the electroacoustic device 510. In one or more examples, the piezoelectric thin film layer 514 comprises a thickness x, where 0.1λ<x<0.6λ, and where λ is the wavelength of the acoustic main mode within the piezoelectric thin film layer 514 of the electroacoustic device 510. In one or more examples, the piezoelectric thin film layer 514 may comprise lithium niobate having a thickness of 550 nanometers (nm) with Euler angles of (0°/125°±15°/0°).

In this figure, the TCF compensating layer 513 is located on top of the optional additional layer 512, and in between the piezoelectric thin film layer 514 and the optional additional layer 512. In other examples, which do not comprise the additional layer 512, the TCF compensating layer 513 may be located on top of the substrate 511, and in between the piezoelectric thin film layer 514 and the substrate 511. For the disclosed electroacoustic device 510, the TCF compensating layer 513 may comprise silicon dioxide (SiO₂) having a thickness y, where 0.05λ<y<0.5λ. In one or more examples, the TCF compensating layer 513 may comprise silicon dioxide having a thickness of 550 nm. Alternatively, the TCF compensating layer 513 may comprise doped silicon dioxide, germanium dioxide (GeO₂), or other dielectric thin films with a low sound velocity, such as silicon nitride (Si₃N₄).

For examples of the disclosed electroacoustic device 510 including the optional additional layer 512, the additional layer 512 is located on top of the substrate 511, and in between the TCF compensating layer 513 and the substrate 511. The additional layer 512 may comprise polycrystalline silicon (Si) having a thickness z, where 0.05λ<z<1.0λ. In one or more examples, the additional layer 512 comprises polycrystalline silicon with a thickness of 500 nm. The additional layer 512 has a relative, high acoustic velocity, which improves the waveguiding abilities of the electroacoustic device 510 and reduces the electric losses as well by localizing charge carriers therein. Alternatively, the additional layer 512 may comprise aluminum nitride (AlN), silicon nitride (Si₃Ni₄), diamond (C(s,diamond)), diamond-like carbon (DLC), and/or silicon carbide (SiC) having a thickness a, where 0<a<1.0λ.

For examples of the disclosed electroacoustic device 510 not including the optional additional layer 512, the substrate 511 may have an ion implanted surface layer, an amorphous layer, or a dielectric layer on top of the substrate 511.

The substrate 511 of the disclosed electroacoustic device 510 is located on the bottom of the electroacoustic device 500, and below the optional additional layer 512 or below the TCF compensating layer 513. The substrate 511 comprises a high resistive silicon. For example, a silicon with Euler angles of (−45°±10°, −54°±10°, 60°±20°) or (0°±10°, 0°±10°, 45°±20°) may be used. Alternatively, the substrate 511 may comprise quartz, sapphire (aluminum oxide) (Al₂O₃), glass, spinel (Al₂MgO₄), and/or silicon carbide.

The electrode structure layer 515 of the disclosed electroacoustic device 510 may comprise a conductive material. For example, the electrode structure layer 515 may include a layered structure comprising aluminum (Al) as the main component of the layered structure, and with a thickness b, where 0.05λ<b<0.2λ. In one or more examples, the electrode structure layer 515 may comprise a layer structure comprising aluminum and having a layer thickness of 150 nm. In other examples, the electrode structure layer 515 may be a “heavy electrode” to reduce the velocity of the electroacoustic device 500. For these examples, the electrode structure layer 515 may comprise a copper (Cu)-based electrode system having one or more layers, or may comprise a single “heavy layer” comprising tungsten (W), molybdenum (Mo), titanium (Ti), and/or platinum (Pt).

In one or more examples, one or more dielectric passivation layers may be applied to the top of the electrode structure layer 515. As one example, each dielectric passivation layer may have a thickness d, where 0.0025λ<d<0.2λ. A dielectric passivation layer may comprise silicon nitride, silicon dioxide, silicon oxynitride (SiON), and/or aluminum oxide (Al₂O₃). In one or more examples, a dielectric passivation layer may comprise silicon nitride with a thickness of 10 nm.

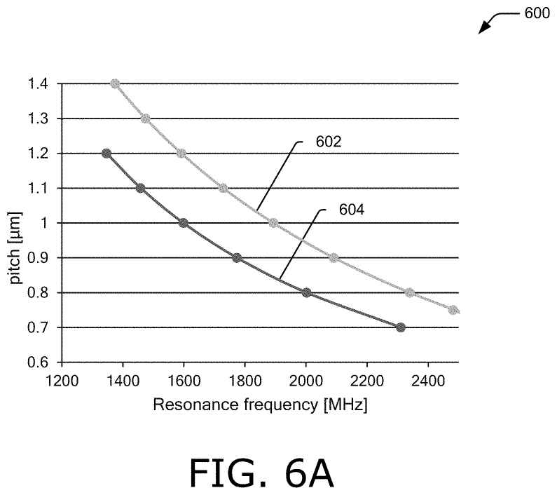

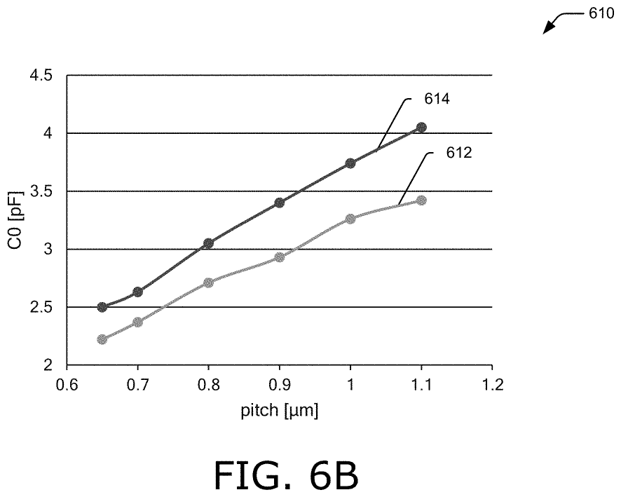

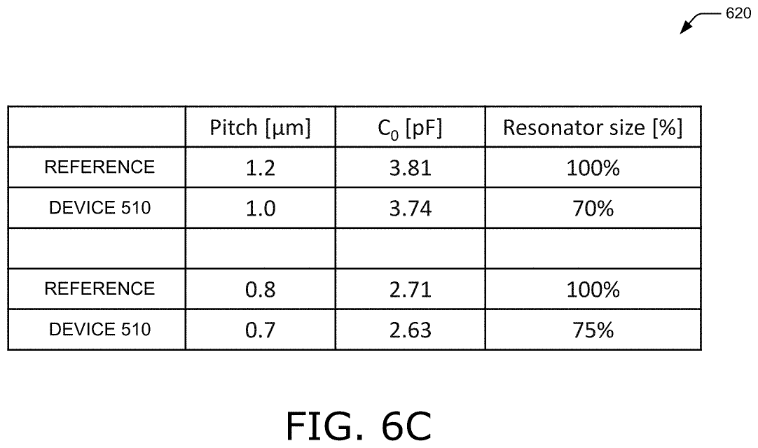

FIG. 6A is a graph 600 showing the differences in pitch versus resonance frequency for the reference electroacoustic device 500 of FIG. 5A and the disclosed electroacoustic device 510 of FIG. 5B. In particular, in this figure, the graph 600 shows the pitch of the IDT in micrometers (μm) versus the resonance frequency (MHz) for the reference electroacoustic device 500 of FIG. 5A (refer to curve 602) and the disclosed electroacoustic device 510 of FIG. 5B (refer to curve 604). The graph 600 shows that the disclosed electroacoustic device 510 of FIG. 5B overall has a lower resonance frequency for the same amount of pitch of the IDT than the electroacoustic device 500 of FIG. 5A.

FIG. 6B is a graph 610 showing the differences in capacitance versus pitch for the electroacoustic device 500 of FIG. 5A and the disclosed electroacoustic device 510 of FIG. 5B. Specifically, in this figure, the graph 610 shows the capacitance (CO) in picofarads (pF) versus the pitch of the IDT in micrometers for the electroacoustic device 500 of FIG. 5A (refer to curve 612) and the disclosed electroacoustic device 510 of FIG. 5B (refer to curve 614). The graph 610 shows that the disclosed electroacoustic device 510 of FIG. 5B overall has a higher capacitance for the same amount of pitch of the IDT than the electroacoustic device 500 of FIG. 5A.

FIG. 6C is a table 620 showing the differences in device size for the reference electroacoustic device 500 of FIG. 5A and the disclosed electroacoustic device 510 of FIG. 5B. In this figure, the table 620 shows that the disclosed electroacoustic device 510 of FIG. 5B (refer to the device 510 rows in the table 620) has a reduction in size (e.g., by 30 percent (%) or by 25%) for approximately the same amount of capacitance as compared to the electroacoustic device 500 of FIG. 5A (refer to the Reference rows in the table 620).

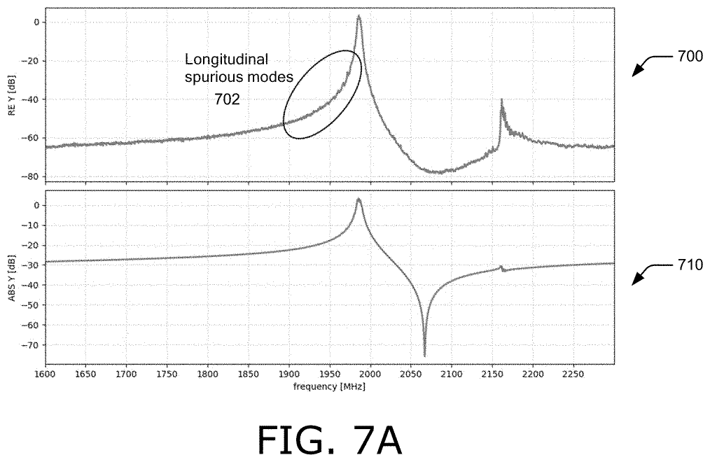

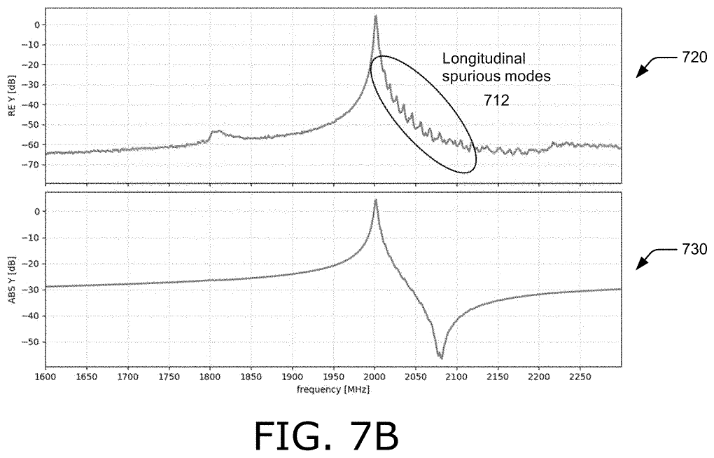

FIG. 7A are performance graphs 700, 710 for the electroacoustic device 500 of FIG. 5A, which shows the longitudinal spurious modes 702 located below the resonance frequency at the lower stopband edge. Graph 700 shows the real value of admittance (RE) in decibels (dB) versus the frequency in MHz, and graph 710 shows the absolute value of admittance (ABS) in dB versus the frequency in MHz. Graph 700 shows that the electroacoustic device 500 of FIG. 5A produces longitudinal spurious modes 702 below the resonance frequency at the lower stopband edge. It should be noted that these longitudinal spurious modes appear in synchronous resonators (e.g., resonators having identical and uniform pitch in the IDT and reflectors).

FIG. 7B are performance graphs 720, 730 for the disclosed electroacoustic device 510 of FIG. 5B, which shows the longitudinal spurious modes 712 located above the resonance frequency at the upper stopband edge, in accordance with examples described herein. Graph 720 shows the real value of admittance in dB versus the frequency in MHz, and graph 730 shows the absolute value of admittance in dB versus the frequency in MHz. Graph 720 shows that the disclosed electroacoustic device 510 of FIG. 5B produces longitudinal spurious modes 712 above the resonance frequency at the upper stopband edge.

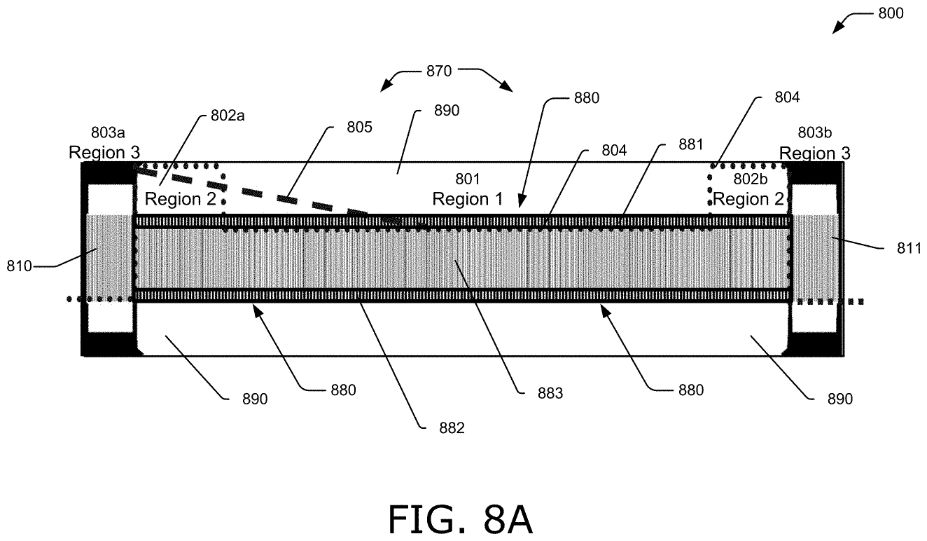

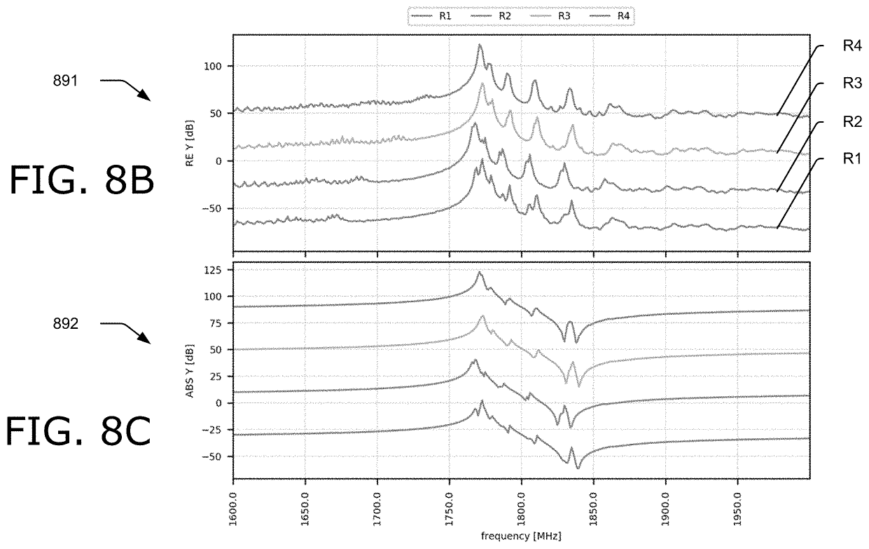

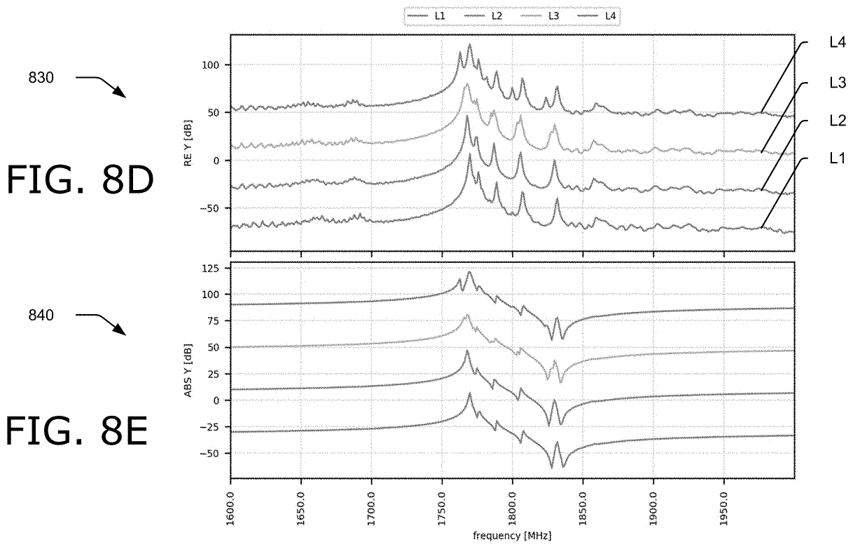

FIG. 8A is a diagram of a view of an example electroacoustic resonator 800, in accordance with examples described herein. In this figure, the disclosed resonator 800 provides a sandwich-based layer stack (e.g., refer to 510 of FIG. 5B) that uses a Rayleigh wave and has a resonance at the upper stopband edge with reduced spurious modes. Similar to the device 100 illustrated in FIG. 1A (e.g., which includes electrode structure 104 on piezoelectric material 102), the electroacoustic resonator 800 includes electrode structure 870 on piezoelectric material 890. The electrode structure 870 includes a first reflector 810, a second reflector 811, and an IDT 880 positioned between the first reflector 810 and the second reflector 811. The IDT 880 includes a central channel section having a plurality of electrode fingers 883, a first busbar 881 (e.g. shown above the electrode fingers 883 in FIG. 8A), and a second busbar 882 (e.g., shown below the electrode fingers 883 in FIG. 8A). The disclosed electrode structure 870 is separated into five areas by pitch, which include Region 1 801, Region 2 802a, Region 2 802b, Region 3 803a, and Region 3 803b. Region 1 801, Region 2 802a, and Region 2 802b correspond to regions of the IDT 880. Region 3 803a and Region 3 803b correspond to regions of reflectors 810 and 811. Region 2 802a is on one side of Region 1 801 and Region 2 802b is on the other side of Region 1 801 so that region 1 801 is between Region 2 802a and Region 2 802b. The IDT including Region 1 801, Region 2 802a, and Region 2 802b is between the reflectors 810 and 811 including Region 3 803a and Region 3 803b. Other examples can include different region configurations, or additional regions, in accordance with the details described herein that may be used in conjunction with an electroacoustic device that primarily relies on a Rayleigh wave.

The pitch ratio together with the slope of the pitch in the transition region (e.g., the transition between the IDT (i.e. Region 1 801, Region 2 802a, and Region 2 802b) and the reflectors (i.e. Region 3 803a and Region 3 803b)) of the disclosed electroacoustic resonator 800 are designed such that the longitudinal spurious modes (refer to 712 of FIG. 7B) are suppressed. In particular, Region 1 801, which is a center region of the IDT (or at least is between Region 2 802a and Region 2 802b), has a pitch that is at a first pitch level (and in many applications may be substantially constant across Region 1 801). Region 2 802a and Region 2 802b, which are on the opposite ends of the IDT, each a pitch that is higher than the pitch in Region 1 801. In some implementations, Region 2 802 and Region 2 802b may have an increasing pitch towards the reflectors (i.e. Region 3 803a and Region 3 803b). The pitch in the reflectors (i.e. Region 3 803a and Region 3 803b) is lower compared to the pitch in the IDT (i.e. the pitch is lower than the pitch in any of Region 1, Region 2 802a, and Region 2 802b). Note that having the pitch in the reflectors lower than the pitch in the IDT is generally contrary to other pitch designs used for electroacoustic devices that have resonance at the lower stopband edge.

For the disclosed electroacoustic resonator 800, the pitch in Region 2 802a and the pitch in Region 2 802b are each larger than the pitch in Region 1 801. In one or more examples, the pitch in Region 2 802a and Region 2 802b is substantially constant across the Region 2 802a and Region 2 802b. In some examples, the pitch level in Region 2 802a and Region 2 802b divided by the pitch level in Region 1 801 is larger than one (1). In one or more other examples, the pitch in Region 2 802a and Region 2 802b is chirped (e.g., the pitch varies over the region). In some examples, where the pitch is chirped, the highest pitch, the pitch level in Region 2 802a and Region 2 802b divided by the pitch level in Region 1 801 is larger than one (1).

The dotted line 804 illustrated in FIG. 8A shows the relative pitch levels of the different areas of the disclosed electroacoustic resonator 800. It should be noted that, in one or more examples, the pitch in Region 2 802a and the pitch in Region 2 802b may be at a constant level as depicted by the dotted line 804. As such, all of the regions (e.g., refer to dotted line 804) may be designed to have a constant pitch (e.g., a stepwise change of pitch between the different regions). As illustrated, the pitch in Region 2 802a and Region 2 802b is higher than the pitch in Region 1 801, while the pitch in Region 3 803a and Region 3 803b is lower than the pitch in Region 1 801, Region 2 802a, and Region 2 802b.

In other examples, the pitch in Region 2 802a and the pitch in Region 2 802b may be chirped in a way where the change in pitch over the region is sloped (e.g., refer to the example sloped pitch for Region 2 802a depicted by dashed line 805). In an example, the pitch in Region 2 802a starts at a first level an increases towards a reflector 810 (and similarly for Region 2 802b increasing towards the corresponding reflector 811. As such, Region 2 802a (e.g., refer to dashed line 805) and/or Region 2 802b may be designed to have a linear change of pitch. In one or more examples, for an exemplary chirp design for the disclosed electroacoustic device, five (5) to 30 electrode fingers of Region 2 802a and/or of Region 2 802b may be designed to have a range of up to a 5% increase in pitch compared to the pitch of Region 1 801. In other examples, increases above 5% are possible. In at least one example, the pitch of the reflectors of Region 3 803a and/or Region 3 803b may be up to 10% lower than the pitch of Region 1 801. In other examples, increases greater than 10% are used. In various examples, any such differences in pitch between regions (e.g., greater or less than 5%, greater or less than 10%, etc.) may be used in a given implementation that meets the possible pitch structures of a given manufacturing process and that results in a Rayleigh wave as a main propagating acoustic wave as described herein.

As illustrated in the aspects shown in FIG. 8A, in some aspects, the resonator 800 is provided. The resonator 800 includes the piezoelectric material 890 (e.g., similar to the piezoelectric material 102 of FIG. 1A). The resonator 800 also includes the IDT 880 positioned at a surface (e.g., the surface shown in the top down view of FIG. 8A, opposed to an opposite surface) of the piezoelectric material 890. The IDT 880 includes a first busbar 881, a second busbar 882 parallel to the first busbar 881, and a plurality of IDT electrode fingers 883 comprising first IDT electrode fingers extending from the first busbar 881 toward the second busbar 882 and second IDT electrode fingers extending from the second busbar 882 toward the first busbar 881 (e.g., similar to the electrode fingers of track 429 illustrated in FIG. 4). The IDT 880 has a plurality of IDT regions as described above, including a first region, shown as region 2 802a and a second region, shown as region 2 802b. The plurality of IDT regions of the IDT 880 also includes a middle or center IDT region, shown as region 1 801. The center region or region 1 801 is between the first IDT region 802a and the second IDT region 802b. A pitch of the IDT electrode fingers 883 in the center IDT region or region 1 801 is at a first pitch level. The pitch of the IDT electrode fingers 883 in the first IDT region of region 2 802a is at a second pitch level. The pitch of the IDT electrode fingers 883 in the second IDT region of region 2 802b is at the second pitch level. The second pitch level is higher than the first pitch level. The resonator 800 also includes a first reflector 810 positioned at the surface of the piezoelectric material 890. The first reflector 810 includes first reflector electrode fingers and has a first reflector region or region 3 803a. The resonator 800 also includes a second reflector 811 positioned at the surface of the piezoelectric material 890, the second reflector 811 including second reflector electrode fingers and having a second reflector region or region 3 803b. The IDT 880 is positioned between the first reflector 810 and the second reflector 811. A reflector pitch of the first reflector 811 in the first reflector region (e.g., region 3 803a) and the second reflector 811 in the second reflector region (e.g., region 3 803b) is at a third pitch level that is lower than the first pitch level and the second pitch level.

In some aspects, the first reflector 810 is positioned at a first end of the IDT 880 and at the surface of the piezoelectric material 890, the first reflector 810 including first reflector electrode fingers and having a first reflector region (e.g., region 3 803a), where the first reflector electrode fingers are approximately parallel to the plurality of IDT electrode fingers 883. In some such aspects, the second reflector 811 positioned at a second end of the IDT opposite the first end of the IDT and at the surface of the piezoelectric material includes second reflector electrode fingers and has a second reflector region (e.g. region 3 803b), wherein the second reflector electrode fingers are approximately parallel to the plurality of IDT electrode fingers 883.

FIGS. 8B and 8C are performance graphs 891, 892 for the disclosed electroacoustic resonator 800 of FIG. 8A comprising various different pitch ratios (R1, R2, R3, R4), in accordance with examples described herein. The pitch ratios (R1, R2, R3, R4) of graphs 891, 892 vary from 1.0 to 1.1. Graph 891 shows the real value of admittance in dB versus the frequency in MHz, and graph 892 shows the absolute value of admittance in dB versus the frequency in MHz. The graphs 891, 892 show that the stopband prior to the resonance frequency can be affected by using the various different pitch ratios.

FIGS. 8D and 8E are performance graphs 830, 840 for the disclosed electroacoustic resonator 800 of FIG. 8A comprising various different trapping lengths (L1, L2, L3, L4), in accordance with examples described herein. Graph 830 shows the real value of admittance in dB versus the frequency in MHz, and graph 840 shows the absolute value of admittance in dB versus the frequency in MHz. By optimizing the pitch ratio together with the slope of the pitch in the transition region of the disclosed electroacoustic resonator 800, the longitudinal spurious modes can be suppressed, which can be seen in FIGS. 8D and 8E. Remaining spurious modes between resonance and antiresonance are common transversal modes, which can be suppressed by a use of other techniques (e.g., could be used in conjunction with a transversal piston mode), which has not been applied to the measurements of FIGS. 8D and 8E. It should be noted that simulations (free of transversal modes) show that the longitudinal spurious modes can be substantially suppressed by employing the disclosed pitch design for the disclosed electroacoustic resonator 800.

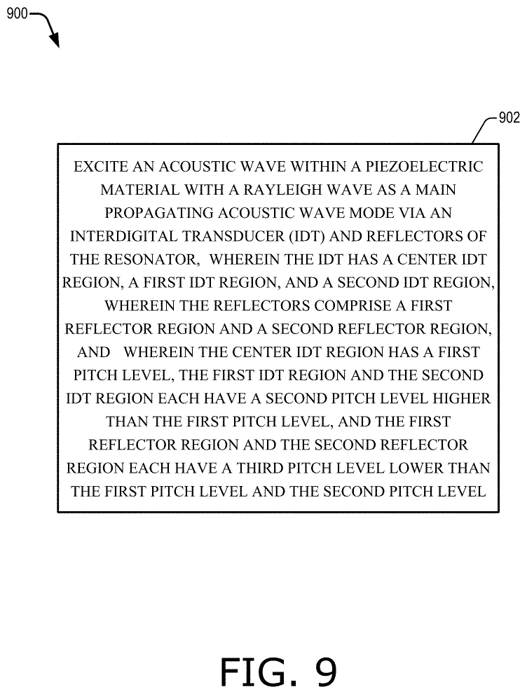

FIG. 9 is a flowchart illustrating a method 900 (or process) of operation of the disclosed electroacoustic device (e.g., 510 of FIG. 5B and/or 800 of FIG. 8A), in accordance with examples described herein. The method 900 is described in the form of a set of blocks that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the method 900, or an alternative approach.

At block 902, the method 900 includes operations to excite an acoustic wave within a piezoelectric material with a Rayleigh wave as a main propagating acoustic wave mode via an interdigital transducer (IDT) and reflectors of the resonator. In accordance with aspects discussed above, such a signal (e.g., the acoustic wave) can be excited by a structure where the IDT has a center IDT region, a first IDT region, and a second IDT region, where the reflectors comprise a first reflector region and a second reflector region, and where the center IDT region has a first pitch level, the first IDT region and the second IDT region each have a second pitch level higher than the first pitch level, and the first reflector region and the second reflector region each have a third pitch level lower than the first pitch level and the second pitch level.

Additional illustrative aspects of the disclosure include:

Aspect 1: A resonator comprising: a piezoelectric material; an interdigital transducer (IDT) positioned at a surface of the piezoelectric material, the IDT comprising: a first busbar; a second busbar parallel to the first busbar; and a plurality of IDT electrode fingers comprising first IDT electrode fingers extending from the first busbar toward the second busbar and second IDT electrode fingers extending from the second busbar toward the first busbar, the IDT having a plurality of IDT regions including a first IDT region, a second IDT region, and a center IDT region between the first IDT region and the second IDT region, wherein a pitch of the IDT electrode fingers in the center IDT region is at a first pitch level, wherein the pitch of the IDT electrode fingers in the first IDT region is at a second pitch level, wherein the pitch of the IDT electrode fingers in the second IDT region is at the second pitch level, and wherein the second pitch level is higher than the first pitch level; a first reflector positioned at the surface of the piezoelectric material, the first reflector comprising first reflector electrode fingers and having a first reflector region; and a second reflector positioned at the surface of the piezoelectric material, the second reflector comprising second reflector electrode fingers and having a second reflector region; wherein the IDT is positioned between the first reflector and the second reflector, and wherein a reflector pitch of the first reflector in the first reflector region and the second reflector in the second reflector region is at a third pitch level that is lower than the first pitch level and the second pitch level.

Aspect 2: The resonator of Aspect 1, wherein the second pitch level is chirped.

Aspect 3: The resonator of any of Aspects 1 to 2, wherein the second pitch level of the first IDT region increases from a lower level to a higher level towards the first reflector region.

Aspect 4: The resonator of any of Aspects 1 to 2, wherein the second pitch level of the second IDT region increases from the lower level to the higher level towards the second reflector region.

Aspect 5: The resonator of any of Aspects 1 to 4, wherein at least some electrode fingers of the IDT electrode fingers in at least one of the first IDT region or the second IDT region have an associated pitch level that is increased compared to the first pitch level of the center IDT region.

Aspect 6: The resonator of Aspect 5, wherein the associated pitch level is increased by less than approximately 5% compared to the first pitch level of the center IDT region.

Aspect 7: The resonator of Aspect 1, wherein the first pitch level is a first constant level, and wherein the second pitch level is a second constant level.

Aspect 8A: The resonator of any of Aspects 1 to 7, wherein the third pitch level is a constant level.

Aspect 8B: The resonator of claims 1 to 7, wherein the third pitch level differs from the first pitch level by at least 10% of the first pitch level.

Aspect 9: The resonator of any of Aspects 1 to 7 and 8A, wherein the third pitch level differs from the first pitch level by less than 10% of the first pitch level.

Aspect 10: The resonator of any of Aspects 1 to 9, wherein the resonator uses a Rayleigh wave as a main propagating wave.

Aspect 11: The resonator of any of Aspects 1 to 10, wherein the resonator generates a resonance frequency at an upper stopband edge.

Aspect 12: The resonator of any of Aspects 1 to 11, further comprising a substrate, wherein the TCF compensating layer is between the substrate and the piezoelectric material.

Aspect 13: The resonator of any of Aspects 1 to 12, wherein the IDT forms an electrode structure layer on top of the surface of the piezoelectric material, and wherein the piezoelectric material is located on top of a temperature coefficient of frequency (TCF) compensating layer.

Aspect 14: The resonator of any of Aspects 1 to 13, wherein the piezoelectric material comprises lithium niobate (LiNbO₃).

Aspect 15: The resonator of any of Aspects 1 to 15, wherein the piezoelectric material comprises a piezoelectric layer having a thickness x, where 0.1λ, x 0.6λ, and where λ is a wavelength of an acoustic main mode within the piezoelectric material.

Aspect 16: The resonator Aspect 15, wherein the cut-angle comprises Euler angles of (0°/125°±15°/0°).

Aspect 17: The resonator of any of Aspects 1 to 16, wherein the piezoelectric material comprises a cut-angle layer configured for excitement and propagation of a Rayleigh wave as a main mode.

Aspect 18: An electrode structure, the electrode structure comprising: an interdigital transducer (IDT) having a center IDT region, a first IDT region, and a second IDT region, wherein the center IDT region has a first pitch level, and wherein the first IDT region and the second IDT region each have a second pitch level higher than the first pitch level; and reflectors comprising a first reflector region and a second reflector region, wherein the first reflector region and the second reflector region each comprise a third pitch level lower than the first pitch level and the second pitch level.

Aspect 19: The electrode structure of Aspect 18, wherein the second pitch level is chirped.

Aspect 20: The electrode structure of any of Aspects 18 to 19, wherein the second pitch level of the first IDT region increases from a lower level to a higher level towards the first reflector region.

Aspect 21: The electrode structure of any of Aspects 18 to 19, wherein the second pitch level of the second IDT region increases from the lower level to the higher level towards the second reflector region.

Aspect 22: The electrode structure of any of Aspects 18 to 21, wherein the third pitch level is a constant level.

Aspect 23: The electrode structure of any of Aspects 18 to 22, wherein the electrode structure forms part of a resonator that uses a Rayleigh wave as a main propagating wave.

Aspect 24: The electrode structure of any of Aspects 18 to 23, wherein the electrode structure forms part of a resonator that generates a resonance frequency at an upper stopband edge.

Aspect 25: The electrode structure of any of Aspects 18 to 24, wherein the electrode structure forms part of a resonator that comprises a piezoelectric layer.

Aspect 26: The electrode structure of Aspect 25, wherein the piezoelectric layer comprises lithium niobate (LiNbO₃).

Aspect 27: The electrode structure of any of Aspects 25 to 26, wherein the piezoelectric layer comprises a thickness x, where 0.1λ x 0.6λ, and where λ is a wavelength of an acoustic main mode within the piezoelectric layer.

Aspect 28: The electrode structure of any of Aspects 25 to 27, wherein the piezoelectric layer comprises a cut-angle configured for excitement and propagation of a Rayleigh wave as a main mode.

Aspect 29: The electrode structure of any of Aspects 25 to 28, further comprising a substrate and a temperature coefficient of frequency (TCF) compensating layer, wherein the TCF compensating layer is between the substrate and the piezoelectric layer.

Aspect 30: A method for operation of a resonator, the method comprising: exciting an acoustic wave within a piezoelectric material with a Rayleigh wave as a main propagating acoustic wave mode via an interdigital transducer (IDT) and reflectors of the resonator, wherein the IDT has a center IDT region, a first IDT region, and a second IDT region, wherein the reflectors comprise a first reflector region and a second reflector region, and wherein the center IDT region has a first pitch level, the first IDT region and the second IDT region each have a second pitch level higher than the first pitch level, and the first reflector region and the second reflector region each have a third pitch level lower than the first pitch level and the second pitch level.

Aspect 31: A method for operating any apparatus, electrode structure, or resonator in accordance with any of any of Aspects 1 to 30, the method involving propagation of a Rayleigh wave.

Aspect 32: An apparatus comprising means for propagating a Rayleigh wave in a resonator in accordance with of any of Aspects 1 to 31.

Aspect 33: A non-transitory computer readable storage medium comprising instructions that, when executed by processing circuitry of a device, cause the device to propagate a Rayleigh wave in accordance with of any of Aspects 1 to 31.

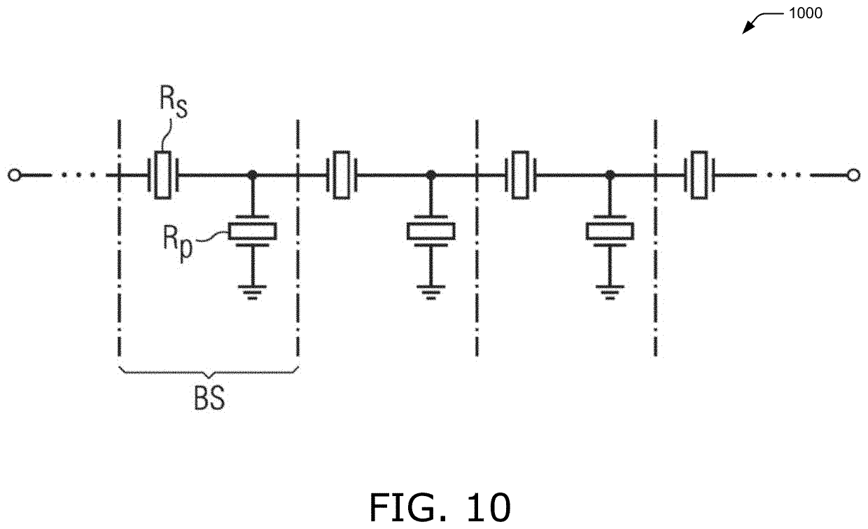

FIG. 10 is a schematic representation of an exemplary filter 1000 that may employ the disclosed electroacoustic device (e.g., 510 of FIG. 5B and 800 of FIG. 8A), in accordance with examples described herein. In particular, the filter 1000 comprises a ladder-type arrangement of acoustic SAW resonators Rs, Rp (where Rs are series resonators and Rp are parallel resonators). The acoustic SAW resonators Rs, Rp are one-port resonators. The disclosed electroacoustic device (e.g., 510 of FIG. 5B and/or 800 of FIG. 8A) may be employed for at least one of the acoustic SAW resonators Rs, Rp of the filter 1000.

The ladder-type structure of the filter 1000 comprises a plurality of basic sections BS. Each basic section BS comprises at least one series resonator Rs and at least one parallel resonator Rp. The basic sections BS may be connected together in series in a number of basic sections BS that is necessary to achieve a desired selectivity. Series resonators Rs that belong to neighbored basic sections BS may be combined to a common series resonator Rs, and parallel resonators Rp may also be combined if they are directly neighbored and belonging to different basic sections BS. One basic section BS provides a basic filter. More basic sections BS are added to provide for sufficient selectivity.

The frequency of the filter 1000 may be adjusted via the pitch of the electrode structure of the resonators Rs, Rp according to the formula f=v/A, where f represents the desired frequency of the filter 1000, v represents the propagation velocity of the acoustic wave, and A is equal to two times the pitch, thereby making the wavelength λ adjustable via the pitch of the IDT, which is formed from the electrode structure.

By using a Rayleigh wave as the main mode of wave propagation for the resonators Rs, Rp, the velocity of the acoustic wave can be reduced by approximately twenty (20) percent (%) from 3800 meters per second (m/s) (for a shear wave SAW resonator) to 3100 m/s (for a Rayleigh wave SAW resonator, such as 510 of FIG. 5B and/or 800 of FIG. 8A).

The Rayleigh wave can be set to be the dominate wave mode by properly selecting the piezoelectric layer of the resonators Rs, Rp in terms of material, thickness, and crystal cut. Also, the thickness and material of the other layers of the layer stack (e.g., refer to 510 of FIG. 5B) of the resonators Rs, Rp can be properly selected to support the desired wave mode.

By using the Rayleigh wave, the pitch of the electrode structure of the resonators Rs, Rp can also be reduced, in some implementations, by approximately 20% in order to achieve the same frequency of a shear wave single-port resonator. In other implementations, other pitch variations can be used. Accordingly, the filter 1000, which is formed by interconnecting a plurality of single-port resonators Rs, Rp, can have a significant reduction in size.

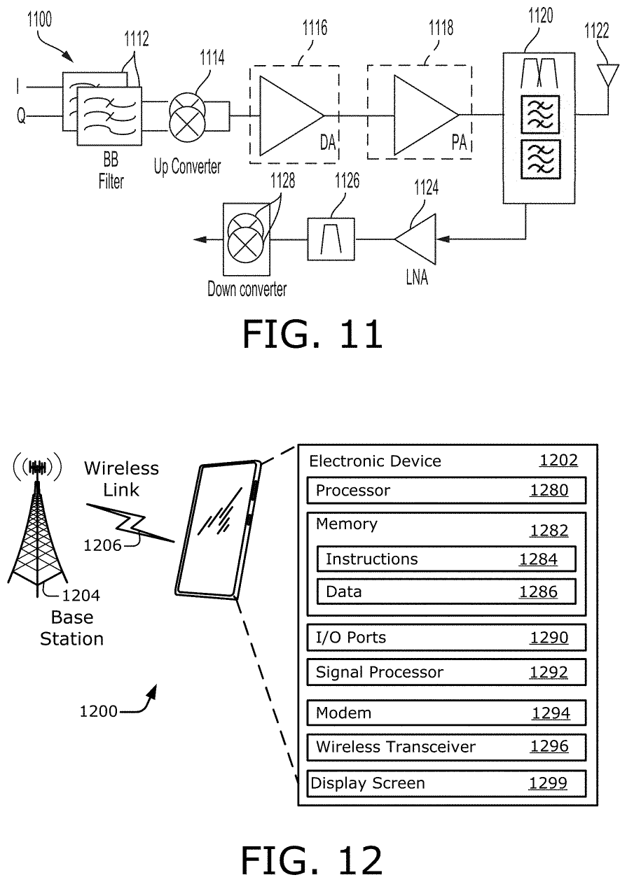

FIG. 11 is a functional block diagram of at least a portion of an example of a simplified wireless transceiver circuit 1100 in which the disclosed electroacoustic device (e.g., 510 of FIG. 5B and/or 800 of FIG. 8A) described herein may be employed. The transceiver circuit 1100 is configured to receive signals/information for transmission (shown as I and Q values) which is provided to one or more base band filters 1112. The filtered output is provided to one or more mixers 1114. The output from the one or more mixers 1114 is provided to a driver amplifier 1116 whose output is provided to a power amplifier 1118 to produce an amplified signal for transmission. The amplified signal is output to the antenna 1122 through one or more filters 1120 (e.g., duplexers if used as a frequency division duplex transceiver or other filters). The one or more filters 1120 may include the disclosed electroacoustic device (e.g., 510 of FIG. 5B and/or 800 of FIG. 8A). The antenna 1122 may be used for both wirelessly transmitting and receiving data. The transceiver circuit 1100 includes a receive path through the one or more filters 1120 to be provided to a low noise amplifier (LNA) 1124 and a further filter 1126 and then down-converted from the receive frequency to a baseband frequency through one or more mixer circuits 1128 before the signal is further processed (e.g., provided to an analog digital converter and then demodulated or otherwise processed in the digital domain). There may be separate filters for the receive circuit (e.g., may have a separate antenna or have separate receive filters) that may be implemented using the disclosed electroacoustic device (e.g., 510 of FIG. 5B and/or 800 of FIG. 8A).

FIG. 12 is a diagram of an environment 1200 that includes an electronic device 1202 that includes a wireless transceiver 1296, such as the transceiver circuit 1100 of FIG. 11. In some aspects, the electronic device 1202 includes a display screen 1299 that can be used to display information associated with data transmitted via wireless link 1206 and processed using components of electronic device 1202 described below. Other aspects of an electronic device in accordance with aspects described herein using a low phase delay filter for multi-band communication can be configured without a display screen. In the environment 1200, the electronic device 1202 communicates with a base station 1204 through a wireless link 1206. As shown, the electronic device 1202 is depicted as a smart phone. However, the electronic device 1202 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, an automobile including a vehicle-based communication system, Internet of Things (IoT) device, sensor or security device, asset tracker, and so forth.

The base station 1204 communicates with the electronic device 1202 via the wireless link 1206, which may be implemented as any suitable type of wireless link. Although depicted as a base station tower of a cellular radio network, the base station 1204 may represent or be implemented as another device, such as a satellite, terrestrial broadcast tower, access point, peer to peer device, mesh network node, fiber optic line, another electronic device generally as described above, and so forth. Hence, the electronic device 1202 may communicate with the base station 1204 or another device via a wired connection, a wireless connection, or a combination thereof. The wireless link 1206 can include a downlink of data or control information communicated from the base station 1204 to the electronic device 1202 and an uplink of other data or control information communicated from the electronic device 1202 to the base station 1204. The wireless link 1206 may be implemented using any suitable communication protocol or standard, such as 3rd Generation Partnership Project Long-Term Evolution (3GPP LTE, 3GPP NR 5G), IEEE 802.11, IEEE 802.16, Bluetooth™, and so forth.

The electronic device 1202 includes a processor 1280 and a memory 1282. The memory 1282 may be or form a portion of a computer readable storage medium. The processor 1280 may include any type of processor, such as an application processor or a multi-core processor, that is configured to execute processor-executable instructions (e.g., code) stored by the memory 1282. The memory 1282 may include any suitable type of data storage media, such as volatile memory (e.g., random access memory (RAM)), non-volatile memory (e.g., Flash memory), optical media, magnetic media (e.g., disk or tape), and so forth. In the context of the disclosure, the memory 1282 is implemented to store instructions 1284, data 1286, and other information of the electronic device 1202, and thus when configured as or part of a computer readable storage medium, the memory 1282 does not include transitory propagating signals or carrier waves.

The electronic device 1202 may also include input/output ports 1290. The I/O ports 1290 enable data exchanges or interaction with other devices, networks, or users or between components of the device.

The electronic device 1202 may further include a signal processor (SP) 1292 (e.g., such as a digital signal processor (DSP)). The signal processor 1292 may function similar to the processor and may be capable executing instructions and/or processing information in conjunction with the memory 1282.

For communication purposes, the electronic device 1202 also includes a modem 1294, a wireless transceiver 1296, and an antenna (not shown). The wireless transceiver 1296 provides connectivity to respective networks and other electronic devices connected therewith using radio-frequency (RF) wireless signals and may include the transceiver circuit 1100 of FIG. 11. The wireless transceiver 1296 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of aspect, an element, or any portion of an element, or any combination of elements described herein may be implemented as a “processing system” that includes one or more processors. Aspects of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout the disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more aspect embodiments, the functions or circuitry blocks described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of aspect, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer. In some aspects, components described with circuitry may be implemented by hardware, software, or any combination thereof.

The phrase “coupled to” and the term “coupled” refers to any component that is physically connected to another component either directly or indirectly, and/or any component that is in communication with another component (e.g., connected to the other component over a wired or wireless connection, and/or other suitable communication interface) either directly or indirectly.

Generally, where there are operations illustrated in figures, those operations may have corresponding counterpart means-plus-function components with similar numbering.

As used herein, the term “determining” encompasses a wide variety of actions. For aspect, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an aspect, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A resonator comprising:
a piezoelectric material;
an interdigital transducer (IDT) positioned at a surface of the piezoelectric material, the IDT comprising:
a first busbar;
a second busbar parallel to the first busbar; and
a plurality of IDT electrode fingers comprising first IDT electrode fingers extending from the first busbar toward the second busbar and second IDT electrode fingers extending from the second busbar toward the first busbar, the IDT having a plurality of IDT regions including a first IDT region, a second IDT region, and a center IDT region between the first IDT region and the second IDT region, wherein a pitch of the IDT electrode fingers in the center IDT region is at a first pitch level, wherein the pitch of the IDT electrode fingers in the first IDT region is at a second pitch level, wherein the pitch of the IDT electrode fingers in the second IDT region is at the second pitch level, and wherein the second pitch level is higher than the first pitch level;
a first reflector positioned at the surface of the piezoelectric material, the first reflector comprising first reflector electrode fingers and having a first reflector region; and
a second reflector positioned at the surface of the piezoelectric material, the second reflector comprising second reflector electrode fingers and having a second reflector region;
wherein the IDT is positioned between the first reflector and the second reflector, and
wherein a reflector pitch of the first reflector in the first reflector region and the second reflector in the second reflector region is at a third pitch level that is lower than the first pitch level and the second pitch level.

2. The resonator of claim 1, wherein the second pitch level is chirped.

3. The resonator of claim 2, wherein the second pitch level of the first IDT region increases from a lower level to a higher level towards the first reflector region.

4. The resonator of claim 3, wherein the second pitch level of the second IDT region increases from the lower level to the higher level towards the second reflector region.

5. The resonator of claim 1, wherein at least some electrode fingers of the IDT electrode fingers in at least one of the first IDT region or the second IDT region have an associated pitch level that is increased compared to the first pitch level of the center IDT region.

6. The resonator of claim 5, wherein the associated pitch level is increased by less than approximately 5% compared to the first pitch level of the center IDT region.

7. The resonator of claim 1, wherein the first pitch level is a first constant level, and wherein the second pitch level is a second constant level.

8. The resonator of claim 1, wherein the third pitch level is a constant level.

9. The resonator of claim 1, wherein the third pitch level differs from the first pitch level by less than 10% of the first pitch level.

10. The resonator of claim 1, wherein the resonator uses a Rayleigh wave as a main propagating wave.

11. The resonator of claim 1, wherein the resonator generates a resonance frequency at an upper stopband edge.

12. The resonator of claim 1, wherein the IDT forms an electrode structure layer on top of the surface of the piezoelectric material, and wherein the piezoelectric material is located on top of a temperature coefficient of frequency (TCF) compensating layer.

13. The resonator of claim 12, further comprising a substrate, wherein the TCF compensating layer is between the substrate and the piezoelectric material.

14. The resonator of claim 1, wherein the piezoelectric material comprises lithium niobate (LiNbO₃).

15. The resonator of claim 14, wherein the piezoelectric material comprises a piezoelectric layer having a thickness x, where 0.1λ<x<0.6λ, and where λ is a wavelength of an acoustic main mode within the piezoelectric material.

16. The resonator of claim 1, wherein the piezoelectric material comprises a cut-angle layer configured for excitement and propagation of a Rayleigh wave as a main mode.

17. The resonator of claim 16, wherein the cut-angle comprises Euler angles of (0°/125°±15°/0°).

18. An electrode structure, the electrode structure comprising:
an interdigital transducer (IDT) having a center IDT region, a first IDT region, and a second IDT region,
wherein the center IDT region has a first pitch level, and wherein the first IDT region and the second IDT region each have a second pitch level higher than the first pitch level; and
reflectors comprising a first reflector region and a second reflector region,
wherein the first reflector region and the second reflector region each comprise a third pitch level lower than the first pitch level and the second pitch level.

19. The electrode structure of claim 18, wherein the second pitch level is chirped.

20. The electrode structure of claim 18, wherein the second pitch level of the first IDT region increases from a lower level to a higher level towards the first reflector region.

21. The electrode structure of claim 20, wherein the second pitch level of the second IDT region increases from the lower level to the higher level towards the second reflector region.

22. The electrode structure of claim 18, wherein the third pitch level is a constant level.

23. The electrode structure of claim 18, wherein the electrode structure forms part of a resonator that uses a Rayleigh wave as a main propagating wave.

24. The electrode structure of claim 18, wherein the electrode structure forms part of a resonator that generates a resonance frequency at an upper stopband edge.

25. The electrode structure of claim 18, wherein the electrode structure forms part of a resonator that comprises a piezoelectric layer.

26. The electrode structure of claim 25, wherein the piezoelectric layer comprises lithium niobate (LiNbO₃).

27. The electrode structure of claim 25, wherein the piezoelectric layer comprises a thickness x, where 0.1λ<x<0.6λ, and where λ is a wavelength of an acoustic main mode within the piezoelectric layer.

28. The electrode structure of claim 25, wherein the piezoelectric layer comprises a cut-angle configured for excitement and propagation of a Rayleigh wave as a main mode.

29. The electrode structure of claim 25, further comprising a substrate and a temperature coefficient of frequency (TCF) compensating layer, wherein the TCF compensating layer is between the substrate and the piezoelectric layer.

30. A method for operation of a resonator, the method comprising:
exciting an acoustic wave within a piezoelectric material with a Rayleigh wave as a main propagating acoustic wave mode via an interdigital transducer (IDT) and reflectors of the resonator,
wherein the IDT has a center IDT region, a first IDT region, and a second IDT region,
wherein the reflectors comprise a first reflector region and a second reflector region, and
wherein the center IDT region has a first pitch level, the first IDT region and the second IDT region each have a second pitch level higher than the first pitch level, and the first reflector region and the second reflector region each have a third pitch level lower than the first pitch level and the second pitch level.
